(19) United States
(12) Patent Application Publication
(10) Pub. No.: US 2014/0262798 A1
(43) Pub. Date: Sep. 18, 2014

(54) ELECTRODEPOSITION METHODS AND BATHS FOR USE WITH PRINTED CIRCUIT BOARDS AND OTHER ARTICLES

(71) Applicant: Xtalic Corporation, Marlborough, MA (US)

(72) Inventors: John Cahalen, Somerville, MA (US); Jacob Sylvester, Gardner, MA (US); Donald M. Baskin, Sudbury, MA (US); Stephen Lucas, Port Charlotte, FL (US); Allen Jones, Marlborough, MA (US)

(21) Appl. No.: 13/839,913

(22) Filed: Mar. 15, 2013

(51) Int. Cl. H05K 3/18

(52) U.S. Cl. CPC H05K 3/188
USPC 205/105; 205/125

(57) ABSTRACT

Electrodeposition methods for use with printed circuit boards and other articles are provided.

### FIELD OF INVENTION

This invention relates generally to electrodeposition methods and baths for use with printed circuit boards and other articles.

### BACKGROUND OF INVENTION

Electrodeposition is a common technique for depositing material on a substrate. Electrodeposition generally involves applying a voltage to a substrate placed in an electrodeposition bath to reduce metal ionic species within the bath which deposit on the substrate in the form of a metal, or metal alloy, coating. The voltage may be applied between an anode and a cathode using a power supply. At least one of the anode or cathode may serve as the substrate to be coated. In some electrodeposition processes, the voltage may be applied as a complex waveform such as in pulse plating, alternating current plating, or reverse-pulse plating.

A variety of metal and metal alloy coatings may be deposited using electrodeposition. For example, metal alloy coatings can be based on two or more transition metals. Tungsten-based coatings are one example of an electrodeposited coating. Such coatings may be tungsten alloys including one or more of the elements Ni, Fe, Co, B, S, and P.

### SUMMARY OF INVENTION

Electrodeposition methods and baths for use with printed circuit boards and other articles are generally provided.

In some embodiments, methods are provided comprising providing an article comprising a polymeric material in an electrodeposition bath, the electrodeposition bath comprising nickel ionic species and tungsten ionic species and having a pH between 5.8 and 7.25; and electrodepositing a nickel-tungsten alloy coating on the article. In some embodiments, the polymeric material is a polymeric masking material.

Other aspects, embodiments, and features of the invention will become apparent from the following detailed description when considered in conjunction with the accompanying drawings. The accompanying figures are schematic and are not intended to be drawn to scale. For purposes of clarity, not every component is labeled in every figure, nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### BRIEF DESCRIPTION OF DRAWINGS

FIG. 1 shows an electrodeposition system according to an embodiment.

FIG. 2 shows an example of a waveform comprising a reverse pulse sequence according to an embodiment.

FIG. 3 shows an example of a waveform comprising (i) a first segment including a single, forward pulse and (ii) a second segment including a reverse pulse sequence.

FIG. 4 shows a plot of % mass loss of a polymeric masking material versus pH of an electrodeposition bath, according to some embodiments.

FIG. 5 shows a plot of the plating rate versus pH of an electrodeposition bath, according to some embodiments.

### DETAILED DESCRIPTION

Electrodeposition methods and baths are described. The methods involve electrodepositing coatings from baths having selected characteristics to promote formation of coatings that exhibit desirable properties. The coatings may comprise a metal alloy including tungsten alloys such as nickel-tungsten alloys. As described further below, the chemistry and pH of the baths may be selected to enable deposition of high quality coatings on articles (e.g., printed circuit boards) that comprise a polymeric material (e.g., a polymeric masking material such as a photoresist) which may be challenging to coat using conventional chemistry and pH conditions.

In some embodiments, methods are provided for depositing a coating on an article comprising a polymeric material, for example, a polymeric masking material. Polymeric materials (e.g., polymeric masking materials) are often employed in the manufacture of articles wherein a portion of the article is associated with a polymeric masking material to protect the portion of the article from certain conditions employed in the manufacture of the article. For example, polymeric masking materials are employed during the manufacture of printed circuit boards, wherein a polymeric masking material is deposited on the surface of the circuit board to protect the underlying metal or metal alloy layers during etching processes. Generally during the electrodeposition process, a portion or all of the polymeric masking material (e.g., associated with the article) is exposed to the electrodeposition bath.

The methods provided herein relate to methods for electrodepositing a nickel-tungsten alloy on articles using an electrodeposition bath. The article, in some embodiments, is associated with a polymeric masking material. Following deposition of the coating, the polymeric masking material may be removed from the article, for example, via exposure to a developing solution (e.g., an alkaline solution having a high pH). In some embodiments, a metal layer may be electrodeposited on the nickel-tungsten alloy coating.

The inventors have discovered that use of electrodeposition baths having certain chemistries and a pH within a specific range provide improved coatings on articles associated with polymeric masking materials. In some embodiments, the lower pH of the operable range of the electrodeposition bath was found to be related to the solubility of one or more of the electrodeposition bath components, for example, the solubility of the tungsten ionic species. In some embodiments, the higher pH of the operable range of the electrodeposition bath was related to the deterioration of the polymeric masking material in the electrodeposition bath. It was surprisingly found, that although many of the polymeric masking materials are known to have stability to high pH levels and the typical developing solutions (e.g., solution employed for removing the polymeric masking material from the article; pH generally 10 or higher), use of electrodeposition baths with pH levels significantly below the pH of the developing solution (e.g., pH of 8) still resulted in deterioration of the polymeric masking material and/or adversely affected the coatings formed using the electrodeposition baths. In some embodiments, use of an electrodeposition bath having a pH in a particular range was found to reduce or prevent any deterioration of a polymeric masking material associated with the article, which may result in the coating depositing on unwanted areas of the article. In some embodiments, the pH of the electrodeposition bath is between 5.8 and 7.25, or between 5.8 and 7, or between 6.25 and 7.25, or between 6.25 and 7, or between 6.5 and 7, or between 6.6 and 6.9, or between 6.5 and 6.75.

As noted above, in some cases, the coated articles are printed circuit board structures. It should be understood that the coatings may be used in connection with forming other types of articles comprising a polymeric masking material (e.g., photoresist material). A printed circuit board, or PCB, can be used to mechanically support and electrically connect electronic components. For example, the coatings described herein may be formed on the printed circuit board's connectors (e.g., edge connectors) which have terminals (also referred to as “tabs” or “fingers”). Other portions of the printed circuit board may also be coated, for example, through holes or other features. In some cases, only the connector portions of the printed circuit boards are coated with the coatings described herein. In such cases, during the electrodeposition process, the other portions of the printed circuit boards may be covered, for example, with a polymeric masking material (e.g., a photoresist), while exposing the connector portions to be coated.

It should be understood that, as used herein, further examples of printed circuit board structures include smart cards, memory cards, thumb drives, and the like. Such cards can be formed with embedded integrated circuits. The cards may be formed of plastic materials such as polyvinyl chloride, but sometimes acrylonitrile butadiene styrene or polycarbonate.

Polymeric masking materials are known to those of ordinary skill in the art. In some embodiments, the polymeric masking materials may be polymers which are susceptible to alkaline conditions. Such polymeric masking material may be removed from the article by exposing the article to a developing solution (e.g., an alkaline solution). Non-limiting examples of polymeric masking materials include photoresist materials and ink-jetting materials (e.g., polymeric and/or wax based materials). The polymeric masking material is generally applied to the portion of an article in a pattern to protect the portion of the article.

Photoresist materials will be known in the art. Generally, a photoresist material is a light sensitive material that when exposed to light (e.g., UV light) becomes more or less soluble to a developer, while the portion of the photoresist that is non-exposed (or exposed less) becomes less or more soluble, respectively, to the developer. Non-limiting examples of photoresist materials include polymers comprising acrylate and/or urethane acrylate monomers, and phenolic resins (e.g., novolac). The photoresist may be a positive photoresist or a negative photoresist.

The electrodeposition baths generally comprise a fluid carrier for the metal source(s) and additive(s). In some embodiments, the fluid carrier is water. However, it should be understood that other fluid carriers may also be used. Those of ordinary skill in the art are able to select suitable fluid carriers.

In some cases, the operating range for the electrodeposition baths described herein is 30-100° C., 40-90° C., 50-80° C., or, in some cases, 50-70° C. In some embodiments, the bath has an operating range of 52-58° C., or 53-57° C. However, it should be understood that other temperature ranges may also be suitable.

The baths include suitable metal sources for depositing a coating with the desired composition. When depositing a metal alloy, it should be understood that all of the metal constituents in the alloy have sources in the bath. The metal sources are generally ionic species that are dissolved in the fluid carrier. As described further below, during the electrodeposition process, the ionic species are deposited in the form of a metal, or metal alloy, to form the coating. In general, any suitable ionic species can be used. The ionic species may be metal salts. For example, sodium tungstate, ammonium tungstate, tungstic acid, etc. may be used as the tungsten source when depositing a coating comprising tungsten; and, nickel sulfate, nickel hydroxy carbonate, nickel carbonate, nickel hydroxide, etc. may be used as the nickel source to deposit a coating comprising tungsten. In some cases, the ionic species may comprise molybdenum. It should be understood that these ionic species are provided as examples and that many other sources are possible.

The bath may comprise nickel ionic species in any suitable concentration (e.g., the concentration of Ni ions), for example, between 5 and 10 g/L, between about 5.85 and 7.15 g/L, or between about 6.25 and 6.75 g/L. The bath may comprise tungsten ionic species in any suitable concentration (e.g., the concentration of W ions), for example, between 5 and 40 g/L, or between 10 and 40 g/L, or between about 29 and 36 g/L, or between about 30 and 35 g/L. Other amounts are possible. See, for example, the bath disclosed in commonly-owned U.S. Application Publication No. 2012/0328904, published on Dec. 27, 2012, which is incorporated herein by reference in its entirety.

In some embodiments, the nickel ionic species (e.g., provided as nickel sulfate hexahydrate) is provided to the bath in a solution comprising citric acid (or other acid) and the tungsten ionic species (e.g., provided as sodium tungstate dihydrate) is provided to the bath in a solution comprising ammonium hydroxide (or other base).

The amounts of acid and/or base in the solutions may be adjusted so that the final bath comprising the nickel ionic species, the tungsten ionic species, and optionally other additives has the desired pH (e.g., between 5.8 and 7.25, or between 5.8 and 7, or between 6.25 and 7.25, or between 6.25 and 7, or between 6.5 and 7, or between 6.6 and 6.9, or between 6.5 and 6.75). Additional acid and/or base may be added to the electrodeposition bath during the electrodeposition process to maintain the pH of the bath in the desired range. In some embodiments, the acid or the base added to the electrodeposition bath may be the acid or base which was present in the original bath. In some embodiments, additional ammonium hydroxide (e.g., 1% ammonium hydroxide) is added to the electrodeposition bath to maintain the pH in the desired range. In some embodiments, additional citric acid and/or sulfuric acid is added to the electrodeposition bath to maintain the pH in the desired range. Those of ordinary skill in the art will be aware of methods and techniques for monitoring the pH of an electrodeposition bath, for example, a pH meter.

As described herein, the electrodeposition baths may include one or more components (e.g., additives) that may enhance the performance of the baths in producing coated articles.

In some embodiments, the baths may include at least one brightening agent. The brightening agent may be any species that, when included in the baths described herein, improves the brightness and/or smoothness of the metal coating produced. In some cases, the brightening agent is a neutral species. In some cases, the brightening agent comprises a charged species (e.g., a positively charged ion, a negatively charged ion). In one set of embodiments, the brightening agent may comprise an alkyl group, optionally substituted. In some embodiments, the brightening agent may comprise a heteroalkyl group, optionally substituted.

In some cases, the brightening agent may be an alkynyl alkoxy alkane. For example, the brightening agent may comprise a compound having the following formula,

H—C≡C[CH₂]ₙ—O—[R¹],

wherein n is an integer between 1 and 100, and R¹ is alkyl or heteroalkyl, optionally substituted. In some cases, the R¹ is an alkyl group, optionally substituted with OH or SO₃. In some embodiments, R¹ comprises a group having the formula (R²)ₘ, wherein R² is alkyl or heteroalkyl, optionally substituted, and m is an integer between 3 and 103, such that n is less than or equal to (m−2). In some embodiments, n is an integer between 1 and 5. In some embodiments, m is an integer between 3 and 7. Some specific examples of brightening agents include, but are not limited to, propargyl-oxo-propane-2,3-dihydroxy (POPDH) and propargyl-3-sulfopropyl ether Na salt (POPS). It should be understood that other alkynyl alkoxy alkanes may also be useful as brightening agents.

In some cases, the brightening agent may comprise an alkyne. For example, the alkyne may be a hydroxy alkyne. In some embodiments, the brightening agent may comprise a compound having the following formula,

[R³]ₓ—C≡C—[R⁴]_{y},

wherein R³ and R⁴ can be the same or different and each is H, alkyl, hydroxyalkyl, or amino optionally substituted, and x and y can be the same or different and each is an integer between 1 and 100. In some cases, at least one of R³ or R⁴ comprises a hydroxyalkyl group. In some instances, at least one of R³ or R⁴ comprises an amino functional group. In some embodiments, x and y can be the same or different and are integers between 1-5, and at least one of R³ and R⁴ comprises a hydroxyalkyl group. In an illustrative embodiment, the alkyne is 2-butyne-1,4-diol. In another illustrative embodiment, the alkyne is 1-diethylamino-2-propyne. It should be understood that other alkynes may also be useful as brightening agents within the context of the invention.

In some cases, the brightening agent may be chosen from those molecules falling within the betain family, where a betain is a neutrally charged compound comprised of a positively charged cationic functional group and a negatively charged anionic functional group. Here examples of the cationic side of the betain could be ammonium, phosphonium, or pyridinium groups optionally substituted, and examples of the anionic side could be carboxylic, sulfonic, or sulfate groups. It should be understood that these functional groups are for illustration and are not intended to be limiting.

In some cases, the electrodeposition baths may include a combination of at least two brightening agents. For example, a bath may comprise both a brightening agent comprising an alkynyl alkoxy alkane and a second brightening agent comprising an alkyne.

The baths may comprise the brightening agent in a concentration of from 0.05 g/L to 5 g/L, from 0.05 g/L to 3 g/L, from 0.05 g/L to 1 g/L, or, in some cases, from 0.01 g/L to 1 g/L. In some cases, the baths may comprise the brightening agent in a concentration of from 0.05 g/L to 1 g/L, from 0.05 g/L to 0.50 g/L, from 0.05 g/L to 0.25 g/L, or, in some cases, from 0.05 g/L to 0.15 g/L. Those of ordinary skill in the art would be able to select the concentration of brightening agent, or mixture of brightening agents, suitable for use in a particular application.

Those of ordinary skill in the art would be able to select the appropriate brightening agent, or combination of brightening agents, suitable for use in a particular invention. In some embodiments, the alkynyl alkoxy alkane, alkyne, or other brightening agent may be selected to exhibit compatibility (e.g., solubility) with the eletroplating bath and components thereof. For example, the brightening agent may be selected to include one or more hydrophilic species to provide greater hydrophilicity to the brightening agent. The hydrophilic species can be, for example, amines, thiols, alcohols, carboxylic acids and carboxylates, sulfates, phosphates, polyethylene glycols (PEGs), or derivatives of polyethylene glycol. The presence of a hydrophilic species can impart enhanced water solubility to the brightening agent. For example, R¹, R², and/or R³ as described above may be selected to comprise a hydroxyl group or a sulfate group.

In some cases, the baths may include at least one wetting agent. A wetting agent refers to any species capable of increasing the wetting ability of the electrodeposition bath with the surface of the article to be coated. For example, the substrate may comprise a hydrophilic surface, and the wetting agent may enhance the compatibility (e.g., wettability) of the bath relative to the substrate. In some cases, the wetting agent may also reduce the number of defects within the metal coating that is produced. The wetting agent may comprise an organic species, an inorganic species, an organometallic species, or combinations thereof. In some embodiments, the wetting agent may be selected to exhibit compatibility (e.g., solubility) with the eletroplating bath and components thereof. For example, the wetting agent may be selected to include one or more hydrophilic species, including amines, thiols, alcohols, carboxylic acids and carboxylates, sulfates, phosphates, polyethylene glycols (PEGs), or derivatives of polyethylene glycol, to enhance the water solubility of the wetting agent.

In one set of embodiments, the wetting agent may comprise an aromatic group, optionally substituted. For example, the wetting agent may comprise a naphthyl group substituted with one or more an alkyl or heteroalkyl group, optionally substituted.

In some cases, the wetting agent may comprise a sulfopropylated polyalkoxy napthol having the following formula,

[chemical structure]

wherein R⁵ comprises an alkyl or heteroalkyl group. In some cases, R⁵ comprises a charged group, such as SO₃. For example, the wetting agent may comprise the group, —(CH₂)₃SO₃ In some embodiments, R⁵ may comprise a group having the formula (R⁶)_{q}, wherein R⁶ is alkyl or heteroalkyl, optionally substituted, and q is an integer between 1-100. In an illustrative embodiment, the wetting agent may be Ralufon NAPE 14-90 (Raschig GmbH).

In another set of embodiments, the wetting agent may comprise a fluorocarbon, optionally substituted. The fluorocarbon could be fully or partially fluorinated. The wetting agent could be chosen from the groups of anionic, non-ionic and amphoteric fluorocarbons. For example, an anionic wetting agent may comprise a fluorocarbon substituted with an anionic moiety such as a carboxylate, sulfonate, sulfate, phosphate, etc. An example of an anionic fluorinated wetting agent is C₈F_{F}SO₃Na. Non-ionic wetting agents are substantially non-dissociated in an electroplating bath, for example C₈F₁₇—CH₂—CH₂—O—(CH₂—CH₂—O)ₙ—H. Amphoteric wetting agents have at least one anionic and cationic moiety. An example of an amphoteric fluorinated wetting agent is C₆F₁₃—(CH₂)₂—SO₂—HN—(CH₂)₃—N(CH₃)₂—CH₂—COOH. The wetting agent may be present in any suitable amount.

Additives described herein can be used both individually and/or in any combinations thereof to provide improved coating quality through brightening, leveling and reduction in propensity for surface pitting.

In some embodiments, the electrodeposition bath may include additional additives. For example, the electrodeposition bath may comprise one or more complexing agents. A complexing agent refers to any species which can coordinate with the metallic ions contained in the solution. The complexing agent may be an organic species, such as a citrate ion, or an inorganic species, such as an ammonium ion. In some cases, the complexing agent is a neutral species. In some cases, the complexing agent is a charged species (e.g., negatively charged ion, positively charged ion). Examples of complexing agents include citrates, gluconates, tartrates, and other alkyl hydroxylcarboxylic acids. Generally, a complexing agent, or mixture of complexing agents, may be included in the electrodeposition bath within a concentration range of 10-200 g/L, and, in some cases, within the range of 40-80 g/L. In one embodiment, the complexing agent is a citrate ion. In some embodiments, ammonium ions may be incorporated into the electrolyte bath as complexing agents and to adjust solution pH, as described herein. For example, the electrodeposition bath may comprise ammonium ions in the range of 1-50 g/L, and between 5-30 g/L.

Those of ordinary skill in the art would be able to select the appropriate combination of brightening agent, wetting agent, and/or other additives suitable for use in a particular application. For example, a screening test for selection of a bath component may include electroplating a coating using a particular bath composition as described herein, or series of bath compositions, and comparing the resulting coating(s) formed to determine the bath composition that produces the desired coating or coating characteristic. In one set of embodiments, a series of bath compositions, each including a different brightening agent, may be used to electroplate a series of coatings. The characteristics (e.g., appearance, stability, etc.) of the resulting coatings may then be evaluated to select the appropriate brightening agent. Similar screening tests may also be employed for other bath components, including wetting agent and/or other additives.

As used herein, the term “alkyl” refers to the radical of saturated aliphatic groups, including straight-chain alkyl groups, branched-chain alkyl groups, cycloalkyl(alicyclic) groups, alkyl substituted cycloalkyl groups, and cycloalkyl substituted alkyl groups. The alkyl groups may be optionally substituted, as described more fully below. Examples of alkyl groups include, but are not limited to, methyl, ethyl, propyl, isopropyl, butyl, isobutyl, tert-butyl, 2-ethylhexyl, cyclopropyl, cyclobutyl, cyclopentyl, cyclohexyl, and the like. “Heteroalkyl” groups are alkyl groups wherein at least one atom is a heteroatom (e.g., oxygen, sulfur, nitrogen, phosphorus, etc.), with the remainder of the atoms being carbon atoms. Examples of heteroalkyl groups include, but are not limited to, alkoxy, poly(ethylene glycol)-, alkyl-substituted amino, tetrahydrofuranyl, piperidinyl, morpholinyl, etc.

The terms “alkenyl” and “alkynyl” refer to unsaturated aliphatic groups analogous to the alkyl groups described above, but containing at least one double or triple bond respectively. The “heteroalkenyl” and “heteroalkynyl” refer to alkenyl and alkynyl groups as described herein in which one or more atoms is a heteroatom (e.g., oxygen, nitrogen, sulfur, and the like).

As used herein, the term “substituted” is contemplated to include all permissible substituents of organic compounds, “permissible” being in the context of the chemical rules of valence known to those of ordinary skill in the art. In some cases, “substituted” may generally refer to replacement of a hydrogen with a substituent as described herein. However, “substituted,” as used herein, does not encompass replacement and/or alteration of a key functional group by which a molecule is identified, e.g., such that the “substituted” functional group becomes, through substitution, a different functional group. For example, a “substituted heteroalkyl” must still comprise the heteroalkyl moiety and can not be modified by substitution, in this definition, to become, e.g., an alkyl group. In a broad aspect, the permissible substituents include acyclic and cyclic, branched and unbranched, carbocyclic and heterocyclic, aromatic and nonaromatic substituents of organic compounds. Illustrative substituents include, for example, those described herein. The permissible substituents can be one or more and the same or different for appropriate organic compounds. For purposes of this invention, the heteroatoms such as nitrogen may have hydrogen substituents and/or any permissible substituents of organic compounds described herein which satisfy the valencies of the heteroatoms. This invention is not intended to be limited in any manner by the permissible substituents of organic compounds.

Examples of substituents include, but are not limited to, alkyl, aryl, aralkyl, cyclic alkyl, heterocycloalkyl, hydroxy, alkoxy, aryloxy, perhaloalkoxy, aralkoxy, heteroaryl, heteroaryloxy, heteroarylalkyl, heteroaralkoxy, azido, amino, halogen, alkylthio, oxo, acylalkyl, carboxy esters, carboxyl, carboxamido, nitro, acyloxy, aminoalkyl, alkylaminoaryl, alkylaryl, alkylaminoalkyl, alkoxyaryl, arylamino, aralkylamino, alkylsulfonyl, carboxamidoalkylaryl, carboxamidoaryl, hydroxyalkyl, haloalkyl, alkylaminoalkylcarboxy, aminocarboxamidoalkyl, alkoxyalkyl, perhaloalkyl, arylalkyloxyalkyl, and the like.

A non-limiting example of the components of an electrodeposition bath include nickel sulfate hexahydrate, sodium tungstate, citric acid, a polyalkoxylated naphthol (e.g., as described herein), an alkynyl alkoxy alkane (e.g., as described herein), and ammonium hydroxide.

Various techniques can be used to monitor the contents of the electrodeposition baths. For example, the techniques may determine the concentration of one or more of the additives in the bath such as the brightening agent(s), wetting agent(s), complexing agent(s), etc. If the concentration of the additive(s) is below or above a desired concentration, the bath composition may be adjusted so that the concentration lies within the desired range. For example, see the techniques disclosed in U.S. Patent Application Publication No. 2010/0116675, published on May 13, 2010, incorporated herein by reference. In some embodiments, techniques for determining the concentration of a brightening agent and/or the wetting agent and/or for analyzing the metal-bound species (e.g., via potentiometry or potentiometric titration) may be employed.

FIG. 1 shows an electrodeposition system 10 according to an embodiment. System 10 includes a electrodeposition bath 12. As described further below, the bath includes the metal sources used to form the coating and one or more additives. An anode 14 and cathode 16 are provided in the bath. A power supply 18 is connected to the anode and the cathode. During use, the power supply generates a waveform which creates a voltage difference between the anode and cathode. The voltage difference leads to reduction of metal ionic species in the bath which deposit in the form of a coating on the cathode, in this embodiment, which also functions as the substrate.

It should be understood that the illustrated system is not intended to be limiting and may include a variety of modifications as known to those of skill in the art.

In some cases, the coating may be combined with additional phases. For example, hard particulates of metal, ceramic, intermetallic, or other material might be incorporated into the coating. Other potential phases which may be incorporated will also be recognized by those skilled in the art, such as solid lubricant particles of graphite or MoS₂.

In some embodiments, it may be advantageous for the coating to be substantially free of elements or compounds having a high toxicity or other disadvantages. In some embodiments, it may be advantageous for the coating to be substantially free of elements or compounds that are deposited using species that have a high toxicity or other disadvantages. For example, in some cases, the coating may be free of chromium (e.g., chromium oxide) since it is often deposited using chromium ionic species (e.g., Cr⁶⁺) which are toxic. Such coatings may provide various processing, health, and environmental advantages over previous coatings.

Various substrates may be coated to form coated articles, as described herein. In some cases, the substrate may comprise an electrically conductive material, such as a metal, metal alloy, intermetallic material, or the like. Suitable substrates include steel, copper, aluminum, brass, bronze, nickel, polymers with conductive surfaces and/or surface treatments, transparent conductive oxides, amongst others.

The coating may have any thickness suitable for a particular application. For example, the total coating thickness may be between 10 nm and 1 mm; in some cases, between 100 nm and 200 micron; and, in some cases, between 100 nm and 100 micron. In some cases, the total coating thickness may be between about 0.5 microns and about 10 microns. It should be understood, however, that the coating may also have other thicknesses outside the above-noted ranges.

In some cases, the coatings may have a particular microstructure. For example, at least a portion of the coating may have a nanocrystalline microstructure. As used herein, a “nanocrystalline” structure refers to a structure in which the number-average size of crystalline grains is less than one micron. The number-average size of the crystalline grains provides equal statistical weight to each grain and is calculated as the sum of all spherical equivalent grain diameters divided by the total number of grains in a representative volume of the body. In some embodiments, at least a portion of the coating may have an amorphous structure. As known in the art, an amorphous structure is a non-crystalline structure characterized by having no long range symmetry in the atomic positions. Examples of amorphous structures include glass, or glass-like structures. Some embodiments may provide coatings having a nanocrystalline structure throughout essentially the entire coating. Some embodiments may provide coatings having an amorphous structure throughout essentially the entire coating.

As noted above, the coatings may be a nickel-tungsten alloy coating. Suitable nickel-tungsten alloys have been described in U.S. Pat. No. 7,425,255, issued Sep. 16, 2008. The alloy may comprise varying amounts of nickel and tungsten. In some embodiments, the coating comprises 25-55 wt % tungsten and 75-45 wt % nickel, or 25-50 wt % tungsten and 75-50 wt % nickel, or 30-50 wt % tungsten and 70-50 wt % nickel, or 32-55 wt % tungsten and 68-45 wt % nickel,

In general, the electrodeposition baths can be used in connection with any electrodeposition process. Electrodeposition generally involves the deposition of a coating on a substrate by contacting the substrate with an electrodeposition bath and flowing electrical current between two electrodes through the electrodeposition bath, i.e., due to a difference in electrical potential between the two electrodes. For example, methods described herein may involve providing an anode, a cathode, an electrodeposition bath associated with (e.g., in contact with) the anode and cathode, and a power supply connected to the anode and cathode. In some cases, the power supply may be driven to generate a waveform for producing a coating, as described more fully below. In some embodiments, at least one electrode may serve as the substrate to be coated.

The electrodeposition may be modulated by varying the potential that is applied between the electrodes (e.g., potential control or voltage control), or by varying the current or current density that is allowed to flow (e.g., current or current density control). In some embodiments, the coating may be formed (e.g., electrodeposited) using direct current (DC) plating, pulsed current plating, reverse pulse current plating, or combinations thereof. Pulses, oscillations, and/or other variations in voltage, potential, current, and/or current density, may also be incorporated during the electrodeposition process, as described more fully below. For example, pulses of controlled voltage may be alternated with pulses of controlled current or current density. In general, during an electrodeposition process an electrical potential may exist on the substrate to be coated, and changes in applied voltage, current, or current density may result in changes to the electrical potential on the substrate. In some cases, the electrodeposition process may include the use of waveforms comprising one or more segments, wherein each segment involves a particular set of electrodeposition conditions (e.g., current density, current duration, electrodeposition bath temperature, etc.), as described more fully below.

In some embodiments, a coating, or portion thereof, may be electrodeposited using direct current (DC) plating. For example, a substrate (e.g., electrode) may be positioned in contact with (e.g., immersed within) a electrodeposition bath comprising one or more species to be deposited on the substrate. A constant, steady electrical current may be passed through the electrodeposition bath to produce a coating, or portion thereof, on the substrate.

In some cases, the electrodeposition method involves driving a power supply to generate a waveform to electrodeposit a coating. The waveform may have any shape, including square waveforms, non-square waveforms of arbitrary shape, and the like. As described further below, in some methods such as when forming coatings having different portions, the waveform may have different segments used to form the different portions. However, it should be understood that not all methods use waveforms having different segments.

In some cases, a bipolar waveform may be used, comprising at least one forward pulse and at least one reverse pulse, i.e., a “reverse pulse sequence.” As noted above, the electrodeposition baths described herein are particularly well suited for depositing coatings using complex waveforms such as reverse pulse sequences. In some embodiments, the at least one reverse pulse immediately follows the at least one forward pulse. In some embodiments, the at least one forward pulse immediately follows the at least one reverse pulse. In some cases, the bipolar waveform includes multiple forward pulses and reverse pulses. Some embodiments may include a bipolar waveform comprising multiple forward pulses and reverse pulses, each pulse having a specific current density and duration. In some cases, the use of a reverse pulse sequence may allow for modulation of composition and/or grain size of the coating that is produced.

In some embodiments, a reverse pulse sequence may be applied such that the forward (e.g., positive) current density, when integrated over the duration of the forward current pulse(s), is of a similar magnitude to the reverse (e.g., negative) current density integrated over the duration of the reverse current segment. FIG. 2 shows an example of a reverse pulse sequence, wherein portions A represent the reverse current density integrated over the duration of the reverse current pulse(s) and portions B represent the forward current density integrated over the duration of the forward current pulse(s).

As noted above, some embodiments may include a waveform having more than one segment, each segment including a particular set of electrodeposition conditions. That is, the waveform is different in different segments. For example, the waveform may include one segment comprising at least one forward pulse and at least one reverse pulse (e.g., a bipolar waveform or a reverse pulse sequence), and another segment comprising a single forward, or reverse, pulse. In some cases, the segment having the single pulse may be arranged prior to the segment having the reverse pulse sequence. For example, FIG. 3 shows an example of a waveform comprising (i) a first segment including a single, forward pulse and (ii) a second segment including a reverse pulse sequence, according to one embodiment of the invention. In some cases, the second segment is similar to the waveform shown in FIG. 2. It also should be understood that the waveform may have more segments in addition to the first and second segments.

The methods of the invention may utilize certain aspects of methods described in U.S. Patent Application Publication No. 2010/0116675, published on May 13, 2010, and

U.S. Patent Application Publication No. 2012/0328904, published on Dec. 27, 2012, which are incorporated herein by reference in their entireties.

The following examples are provided for illustration purposes and are not intended to be limiting.

### EXAMPLES

The following examples describe test results relating to electrodeposition baths for depositing a Ni—W coating on articles associated with a photoresist material.

In this example, electrodeposition baths were prepared comprising the following components:

| | Approximate bath |
|---|---|
| Component | concentration |
| Nickel sulfate hexahydrate | 6.5 g/L Nickel metal |
| Sodium Tungstate | 32.5 g/L Tungsten metal |
| Citric Acid | 65 g/L |
| polyalkoxylated naphthol | 0.25 g/L |
| alkynyl alkoxy alkane | 0.1 g/L |
| Ammonium hydroxide | variable to obtain target pH |

The pH of the baths were changed by varying the amount of ammonium hydroxide, unless otherwise stated (e.g., for the titration methods, sulfuric acid was added.

FIG. 4 shows a plot of the % mass loss of a dry film photoresist layer (Kolon KM 11-45, a negative tone, dry film photoresist) after 30 minutes of exposure to an electrodeposition bath at various pHs. The photoresist materials was laminated to a circuit board material and exposed to UV light using the manufacturer's recommended dosage. The thickness of the photoresist was 0.0025 inches thick. The bath was stirred during the exposure. To determine the % mass loss, the photoresist was removed from the bath, rinsed with DI water, dried for 2 hours at 110° C., and the weight change was measured. As the graph shows, the photoresist dissolution rate increase significantly at a pH of greater than about 7. The film dissolution rate was approximately constant at a pH between 6.5-7. Therefore, in some embodiments, the maximum pH of the electrodeposition bath was 7.0 and the minimum pH of the electrodeposition bath was 6.5, or between 6.6 and 6.9.

The lower pH limit for the electrodeposition baths was investigated using chemical titration methods to determine the pH at which tungsten precipitation occurred. Titrations were carried out by adding sulfuric acid to the electrodeposition bath as well as a solution comprising tungsten concentrate comprising 400 g/L sodium tungstate in DI water. Events were observed for both the electrodeposition bath and the tungsten concentrate at a pH of approximately 5.8.

Depositions of Ni—W coatings were carried out on a copper clad laminate substrate. The platting was carried out in a 12.5 L tank that the exposure time was 75 minutes. The results are given in Table 1. In Table 1: NAV=Nitric Acid Vapor (e.g., an industry test method for coating porosity of barrier layers over copper substrates); EDS=Energy Dispersive Spectroscopy (e.g., a standard method for analyzing composition of a material); XRF=X-Ray fluorescence.

TABLE 1

| | | | Deposition |
|---|---|---|---|
| | W wt %, | | Rate by XRF |
| pH | EDS | NAV | microns/min. |
| 7.25 | 42.5 | Comparable | 0.62 |
| 7.00 | 43.8 | performance | 0.56 |
| 6.75 | 42.9 | | 0.52 |
| 6.50 | 41.9 | | 0.52 |

The effects of the bath age were also investigated at a variety of pHs. As shown in FIG. 5, a slight decrease in the plating age was observed as the bath aged. The plating rate stabilized at approximately 60 Ahr/L.

1. A method comprising:
providing an article comprising a polymeric material in an electrodeposition bath, the electrodeposition bath comprising nickel ionic species and tungsten ionic species and having a pH between 5.8 and 7.25; and
electrodepositing a nickel-tungsten alloy coating on the article.

2. The method of claim 1, wherein the pH of the bath is between 6.25 and 7.

3. The method of claim 1, wherein the electrodeposition bath further comprises a brightening agent.

4. The method of claim 1, wherein the electrodeposition bath further comprises a wetting agent.

5. The method of claim 1, wherein the electrodeposition bath further comprises water.

6. The method of claim 1, wherein the electrodeposition bath further comprises a complexing agent.

7. The method of claim 1, wherein the electrodepositing comprises driving the power supply to generate a waveform to electrodeposit a coating on the article.

8. The method of claim 7, wherein the waveform comprises at least one forward pulse and at least one reverse pulse.

9. The method of claim 1, wherein the article is a printed circuit board.

10. The method of claim 1, further comprising removing the masking material from the article.

11. The method of claim 1, wherein the polymeric material is a polymeric masking material.

12. The method of claim 11, wherein the polymeric masking material is a photoresist material.

13. The method of claim 11, wherein the polymeric masking material is an ink-jet material.

14. The method of claim 11, wherein the electrodeposition bath further comprises ammonium.

15. The method of claim 1, wherein the electrodeposition bath comprising between between 5 and 10 g/L nickel ionic species.

16. The method of claim 1, wherein the electrodeposition bath comprising between 5 and 40 g/L tungsten ionic species.

17. The method of claim 1, further comprising electrodepositing a metal layer on the nickel-tungsten alloy coating.

18. The method of claim 1, wherein the nickel-tungsten alloy coating is nanocrystalline.
